(19) United States
(12) Patent Application Publication
(10) Pub. No.: US 2026/0100210 A1
(43) Pub. Date: Apr. 9, 2026

(54) MEMORY CALCULATING TIMING DIFFERENCE BETWEEN COMMAND AND DATA, AND OPERATION METHOD OF MEMORY SYSTEM

(71) Applicant: SK hynix Inc., Gyeonggi-do (KR)

(72) Inventor: Jong Hyuck CHOI, Gyeonggi-do (KR)

(21) Appl. No.: 19/035,865

(22) Filed: Jan. 24, 2025

(30) Foreign Application Priority Data
Oct. 4, 2024 (KR) 10-2024-0134544

(51) Int. Cl. G11C 8/18; G11C 7/10; G11C 8/08

(52) U.S. Cl. CPC G11C 8/18; G11C 7/1093; G11C 8/08

(57) ABSTRACT

A memory may include a command component configured to activate an internal clock after N clock cycles from a reception time point of a measurement command, where N is an integer equal to or greater than 0; and a data component configured to generate a first counting code by counting a data clock, generate a second counting code by counting the internal clock transmitted from the command component, and calculate a command-data timing difference based on a difference between code values of the first counting code and the second counting code.

### CROSS-REFERENCE TO RELATED APPLICATION

This application claims priority under 35 U.S.C. § 119(a) to Korean Patent Application No. 10-2024-0134544 filed on Oct. 4, 2024, which is incorporated herein by reference in its entirety.

### BACKGROUND

### 1. Technical Field

Embodiments of the present disclosure relate to a memory, and more particularly, to a technology of calculating a timing difference between a command block and a data block within a memory.

### 2. Related Art

A memory receives a command and an address from a memory controller, and transmits/receives read and write data to/from the memory controller. Because a command block that receives a command and an address and a data block that transmits/receives data are physically separated within the memory, an asynchronous timing difference exists between the command block and the data block of the memory.

In the memory, because the data block needs to transmit and receive data under the control of the command block, the timing difference between the command block and the data block needs to be accurately measured, and this needs to be reflected in the control within the memory. An operation for measuring such a timing difference includes an operation such as write internal cycle alignment (WICA), and this operation has the disadvantage of taking a lot of time and being complicated because it needs to be performed multiple times while changing the time point at which the memory controller applies the command to the memory.

### SUMMARY

In an embodiment of the present disclosure, a memory may include a command component configured to activate an internal clock after N clock cycles from a reception time point of a measurement command, where N is an integer equal to or greater than 0; and a data component configured to generate a first counting code by counting a data clock, generate a second counting code by counting the internal clock transmitted from the command component, and calculate a command-data timing difference based on a difference between code values of the first counting code and the second counting code.

In an embodiment of the present disclosure, a memory may include a command component configured to generate a start signal that is activated after N clock cycles from a reception time point of a measurement command and receives a clock, where N is an integer equal to or greater than 0; and a data component configured to generate a counting code by counting the clock transmitted from the command component from an activation time point of the start signal transmitted from the command component to a toggling time point of a data clock, and calculate a command-data timing difference based on the counting code.

In an embodiment of the present disclosure, a memory may include a command component configured to activate an internal clock after N clock cycles from a reception time point of a measurement command, where N is an integer equal to or greater than 0; and a data component configured to generate a counting code by counting the internal clock transmitted from the command component up to a toggling time point of a data clock, and calculate a command-data timing difference based on the counting code.

In an embodiment of the present disclosure, a memory may include a command component configured to generate a start signal that is activated after N clock cycles from a reception time point of a measurement command and receive a clock, where N is an integer equal to or greater than 0; and a data component configured to generate a first counting code by counting a data clock, generate a second counting code by counting the clock transmitted from the command component from an activation time point of the start signal transmitted from the command component, and calculate a command-data timing difference based on a difference between code values of the first counting code and the second counting code.

In an embodiment of the present disclosure, an operation method of a memory system including a memory controller and a memory may include transmitting, by the memory controller, a measurement command to the memory; receiving, by the memory, the measurement command; activating, by the memory, an internal signal after N clock cycles from the reception of the measurement command, where N is an integer equal to or greater than 0; starting, by the memory, measuring a time in response to the activating of the internal signal; toggling, by the memory controller, a data clock transmitted to the memory from a time point after M clock cycles from the transmission of the measurement command, where M is an integer greater than N; ending, by the memory, the measuring of the time in response to the toggling of the data clock; and calculating, by the memory, a command-data timing difference based on the measured time.

### BRIEF DESCRIPTION OF THE DRAWINGS

FIG. 1 is a diagram illustrating a configuration of a memory in accordance with a first embodiment of the present disclosure.

FIG. 2 is a timing diagram illustrating a command-data timing difference measurement operation of the memory in FIG. 1.

FIG. 3 is a diagram illustrating a configuration of a memory in accordance with a second embodiment of the present disclosure.

FIG. 4 is a diagram illustrating a configuration of a memory in accordance with a third embodiment of the present disclosure.

FIG. 5 is a diagram illustrating a configuration of a memory in accordance with a fourth embodiment of the present disclosure.

FIG. 6 is a flowchart illustrating an operation of a memory system for measuring a timing difference between a command block and a data block of a memory according to an embodiment of the present disclosure.

### DETAILED DESCRIPTION

Various embodiments of the present disclosure are directed to providing a technology of simply and accurately measuring a timing difference between a command block and a data block of a memory.

In accordance with embodiments of the present disclosure, a timing difference between a command block and a data block of a memory can be simply and accurately measured.

Hereafter, embodiments in accordance with the technical spirit of the present disclosure will be described with reference to the accompanying drawings.

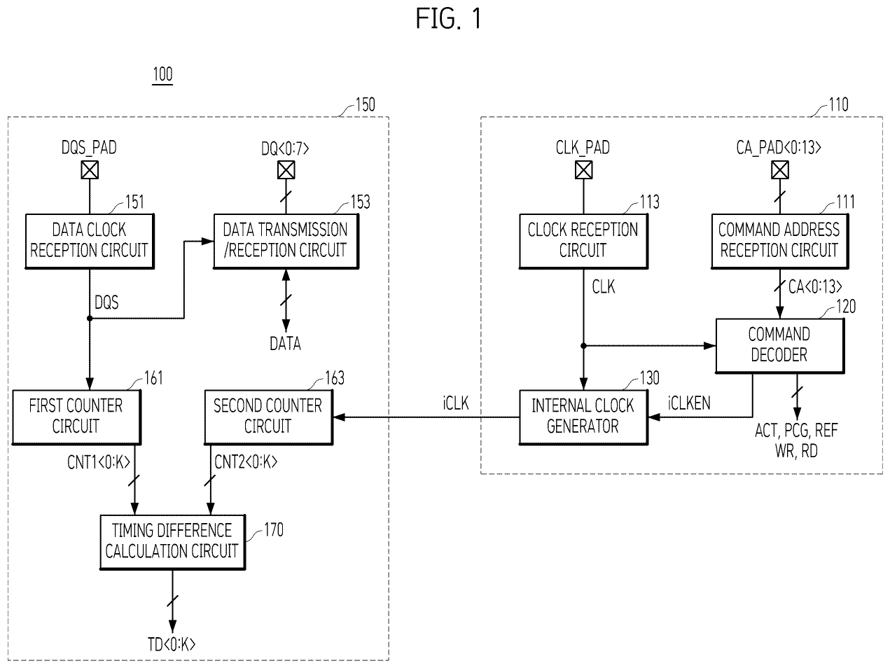

FIG. 1 is a diagram illustrating a configuration of a memory 100 in accordance with a first embodiment of the present disclosure. FIG. 1 illustrates components related to measuring a timing difference between a command block (i.e., a command component) 110 and a data block (i.e., a data component) 150 of the memory 100.

Referring to FIG. 1, the memory 100 may include the command block 110 and the data block 150.

The command block 110 may be a block that receives and processes signals CA<0:13> of command address terminals CA_PAD<0:13> and a clock terminal CLK_PAD. In an embodiment, the command block 110 may include a command address reception circuit 111, a clock reception circuit 113, a command decoder 120, and an internal clock generator 130.

The command address reception circuit 111 may receive command address signals CA<0:13> of the command address terminals CA_PAD<0:13>. The number of command address terminals CA_PAD<0: 13> is 14, but this number may change depending on a type of a memory.

The clock reception circuit 113 may receive a clock CLK of the clock terminal CLK_PAD. FIG. 1 illustrates one clock terminal CLK_PAD, but the clock CLK may be a differential signal and the clock terminal CLK_PAD may also be configured as two terminals for receiving the differential signal.

The command decoder 120 may decode the command address signals CA<0:13>. In an embodiment, the command decoder 120 may operate in synchronization with the clock CLK. The command decoder 120 may generate internal command signals ACT, PCG, REF, WR, and RD as a result of decoding. The active signal ACT is an internal command signal instructing an active operation, the precharge signal PCG is an internal command signal instructing a precharge operation, and the refresh signal REF is an internal command signal instructing a refresh operation. The write signal WR is an internal command signal instructing a write operation, and the read signal RD is an internal command signal instructing a read operation.

When the reception of a measurement command is confirmed as a result of decoding the command address signals CA<0:13>, the command decoder 120 may activate an internal clock activation signal iCLKEN after N clock cycles, where N is an integer equal to or greater than 0, from the reception time point of the measurement command. In an embodiment, the measurement command may be a command for measuring the timing difference between the command block 110 and the data block 150.

The internal clock generator 130 may generate the internal clock iCLK identical to the clock CLK while the internal clock activation signal iCLKEN is activated, and deactivate the internal clock iCLK while the internal clock activation signal iCLKEN is deactivated. In an embodiment, deactivating the internal clock iCLK means fixing the logic level of the internal clock iCLK so that the internal clock iCLK does not toggle.

In an embodiment, the data block 150 may be a block for transmitting/receiving data. Because terminals DQ<0:7> and DQS_PAD related to transmission/reception of the data DATA are physically separated from the command address terminals CA<0:13>, the data block 150 is physically separated from the command block 110. In an embodiment, the data block 150 may include a data clock reception circuit 151, a data transmission/reception circuit 153, a first counter circuit 161, a second counter circuit 163, and a timing difference calculation circuit 170.

The data clock reception circuit 151 may receive a data clock DQS of a data clock terminal DQS_PAD. The data clock DQS may be a data clock used for transmitting/receiving the data DATA. In an embodiment, the data clock DQS toggles when the data DATA is transmitted/received and is deactivated in a section where the data DATA is not transmitted/received. In an embodiment, during a measurement operation in which a measurement command is applied, the data clock DQS starts toggling after M clock cycles, where M is an integer greater than N, from the application of the measurement command. Because the data clock DQS is a signal for strobing the data DATA, the data clock DQS may also be referred to as a data strobe signal.

The data transmission/reception circuit 153 may receive the data DATA of the data terminals DQ<0:7> or transmit the data DATA to the data terminals DQ<0:7>. During a write operation, the data transmission/reception circuit 153 may receive write data DATA transmitted from a memory controller, and during a read operation, the data transmission/reception circuit 153 may transmit read data DATA to the memory controller. In an embodiment, the data transmission/reception circuit 153 may perform transmission/reception operations in synchronization with the data clock DQS.

In an embodiment, the first counter circuit 161 may generate a first counting code CNT1<0:k> by counting the number of activations of the data clock DQS received by the data clock reception circuit 151. The second counter circuit 163 may generate a second counting code CNT2<0:k> by counting the number of activations of the internal clock iCLK transmitted from the command block 110.

The timing difference calculation circuit 170 may calculate a command-data timing difference TD<0:k> by using the first counting code CNT1<0:k> and the second counting code CNT2<0:k>. In an embodiment, the timing difference calculation circuit 170 may calculate the command-data timing difference TD<0:k> by using a difference between the code values of the first counting code CNT1<0:k> and the second counting code CNT2<0:k>.

The internal clock iCLK may be a clock that is activated after the N clock cycles from the reception time point of the measurement command and is transmitted from the command block 110 to the data block 150, and the data clock DQS may be a clock that is activated after the M clock cycles from the reception time point of the measurement command and is input to the data block 150. Therefore, the difference between the code values of the first counting code CNT1<0:k> and the second counting code CNT2<0:k> needs to be M-N. However, when the difference between the code values is less than M-N, this may be regarded as a delay value occurring when the internal clock iCLK is transmitted from the command block 110 to the data block 150, that is, a timing difference between the command block 110 and the data block 150. In an embodiment, by using this principle, the timing difference calculation circuit 170 may generate a difference value between the value of (M-N) and the difference between the code values of the first counting code CNT1<0:k> and the second counting code CNT2<0:k> as the command-data timing difference TD<0:k>. For example, when M=10, N=5, the value of the first counting code CNT1<0:k> is 1, and the value of the second counting code CNT2<0:k> is 4, the command-data timing difference TD<0:k> is generated as 2.

In an embodiment, the command-data timing difference TD<0:k> generated by the timing difference calculation circuit 170 is used for controlling the data block 150 of the command block 110. For example, when a write latency WL is 15 and the command-data timing difference TD<0:k> is 3, three clock cycles are used for transmitting control signals from the command block 110 to the data block 150. Therefore, when the command block 110 controls the data block 150 as if the write latency WL is 12, the data block 150 actually operates at the same timing as if the write latency WL is 15. The command-data latency difference TD<0:k> is also used for controlling a read latency RL. Similarly, when a termination operation of the data block 150 needs to be activated after five clock cycles after the reception of an on-die termination (ODT) command, the command block 110 may instruct the termination operation of the data block 150 after two clock cycles after the reception of the termination command in consideration of the command-data timing difference TD<0:k> (i.e., 3).

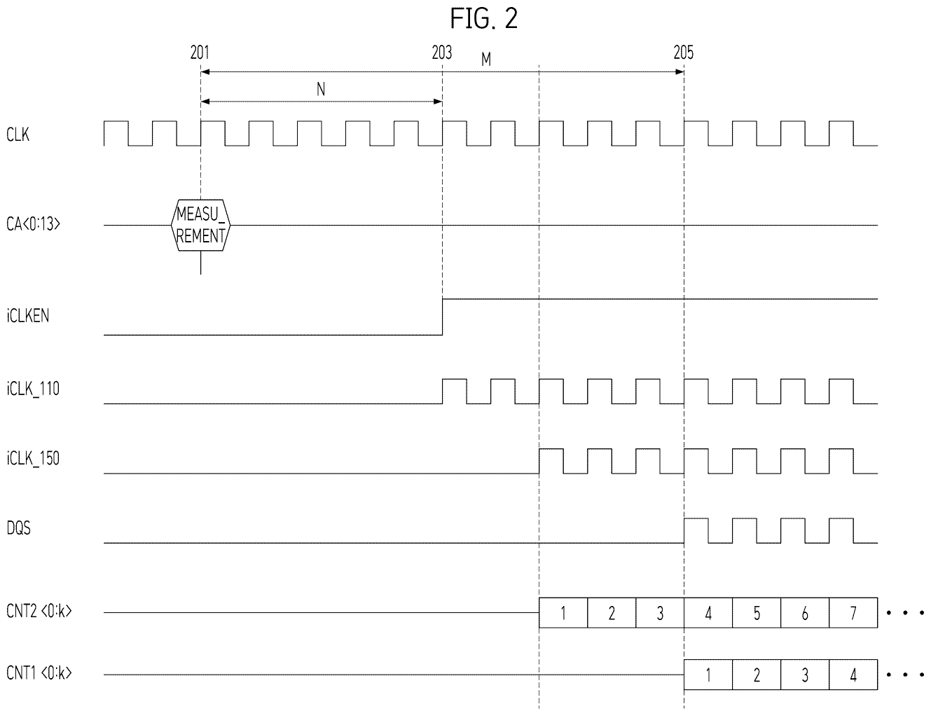

FIG. 2 is a timing diagram illustrating the command-data timing difference measurement operation of the memory 100 in FIG. 1.

Referring to FIG. 2, the measurement command is received at a time point 201. The internal clock generator 130 of the command block 110 activates an internal clock iCLK_110 from a time point 203 after N clock cycles (as an example, N=5) after the reception time point 201 of the measurement command. The internal clock iCLK_110 in the drawing means an internal clock of the command block 110.

The internal clock iCLK_110 generated in the command block 110 is transmitted to the data block 150, but due to a delay in a transmission path from the command block 110 to the data block 150, an internal clock iCLK_150 of the data block 150 is further delayed compared to the internal clock iCLK_110 of the command block 110.

From a time point 205 after M clock cycles (as an example, M=10) from the reception time point 201 of the measurement command, the data clock DQS received by the data clock reception circuit 151 of the data block 150 is activated and toggled.

The first counter circuit 161 of the data block 150 may generate the first counting code CNT1<0:k> by counting the number of activations of the data clock DQS, and the second counter circuit 163 may generate the second counting code CNT2<0:k> by counting the number of activations of the internal clock iCLK_150.

Referring to FIG. 2, the difference between the code values of the first counting code CNT1<0:k> and the second counting code CNT2<0:k> is 3. Because M-N is 5 and the difference between the values of the codes CNT1<0:k> and CNT2<0:k> is 3, the timing difference calculation circuit 170 may generate the command-data timing difference TD<0:k> as 2.

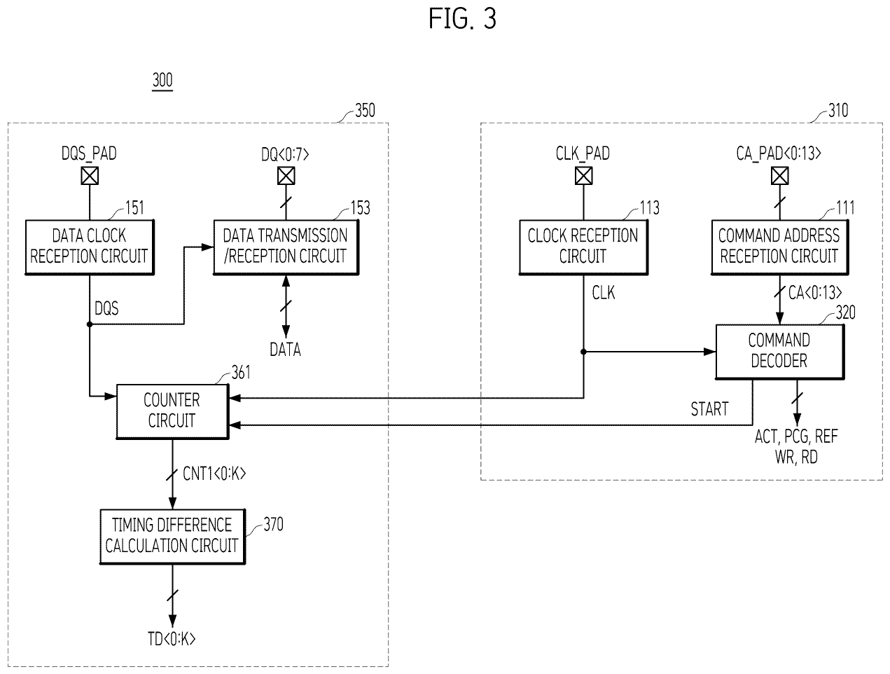

FIG. 3 is a diagram illustrating a configuration of a memory 300 in accordance with a second embodiment of the present disclosure. FIG. 3 illustrates components related to measuring a timing difference between a command block (i.e., a command component) 310 and a data block (i.e., a data component) 350 of the memory 300.

Referring to FIG. 3, the memory 300 may include the command block 310 and the data block 350.

In an embodiment, the command block 310 may include the command address reception circuit 111, the clock reception circuit 113, and a command decoder 320.

The command address reception circuit 111 may receive the command address signals CA<0:13> of the command address terminals CA_PAD<0:13>. The clock reception circuit 113 may receive the clock CLK of the clock terminal CLK_PAD.

The command decoder 320 may decode the command address signals CA<0:13>. In an embodiment, the command decoder 320 may operate in synchronization with the clock CLK. The command decoder 320 may generate the internal command signals ACT, PCG, REF, WR, and RD as a result of decoding. The active signal ACT is an internal command signal instructing an active operation, the precharge signal PCG is an internal command signal instructing a precharge operation, and the refresh signal REF is an internal command signal instructing a refresh operation. The write signal WR is an internal command signal instructing a write operation, and the read signal RD is an internal command signal instructing a read operation.

When the reception of the measurement command is confirmed as a result of decoding the command address signals CA<0:13>, the command decoder 320 may activate a start signal START after N clock cycles from the reception time point of the measurement command. In an embodiment, the measurement command may be a command for measuring the timing difference between the command block 310 and the data block 350.

The clock CLK received by the clock reception circuit 113 of the command block 310 and the start signal START generated by the command decoder are transmitted to the data block 350.

In an embodiment, the data block 350 may include the data clock reception circuit 151, the data transmission/reception circuit 153, a counter circuit 360, and a timing difference calculation circuit 370.

The data clock reception circuit 151 may receive the data clock DQS of the data clock terminal DQS_PAD. The data clock DQS may be a data clock used for transmitting/receiving the data DATA. In an embodiment, the data clock DQS toggles when the data DATA is transmitted/received and is deactivated in a section where the data DATA is not transmitted/received. In an embodiment, during a measurement operation in which a measurement command is applied, the data clock DQS starts toggling after the M clock cycles, where M is an integer greater than N, from the application of the measurement command.

The data transmission/reception circuit 153 may receive the data DATA of the data terminals DQ<0:7> or transmit the data DATA to the data terminals DQ<0:7>. In an embodiment, the data transmission/reception circuit 153 may perform transmission/reception operations in synchronization with the data clock DQS.

In an embodiment, the counter circuit 360 may be activated in response to the activation of the start signal START and deactivated in response to the toggling of the data clock DQS. The counter circuit 360 may count the number of activations of the clock CLK during the activation duration and generate a counting code CNT<0:k>. The start signal START may be a signal that is activated after the N clock cycles from the reception time point of the measurement command and is transmitted from the command block 310 to the data block 350, and the data clock DQS may be a clock that is activated after the M clock cycles from the reception time point of the measurement command and is input to the data block 350. The code value of the counting code CNT<0:k> may correspond to the time from the activation time point of the start signal START transmitted to the data block 350 to the time point when the data clock DQS starts toggling. That is, the code value of the counting code CNT<0:k> in FIG. 3 corresponds to the difference between the code value of the first counting code CNT1<0:k> and the code value of the second counting code CNT2<0:k> of FIG. 1.

The timing difference calculation circuit 370 may generate a difference between the value of (M-N) and the value of the counting code CNT<0:k> as a command-data timing difference TD<0:k>. For example, when M=10, N=5, and the value of the counting code CNT<0:k> is 2, the command-data timing difference TD<0:k> is generated as 3. The command-data timing difference TD<0:k> generated by the timing difference calculation circuit 370 is used for controlling the data block 350 of the command block 310. Examples of control in which the command-data timing difference TD<0:k> is used include write latency control, read latency control, and on-die termination control.

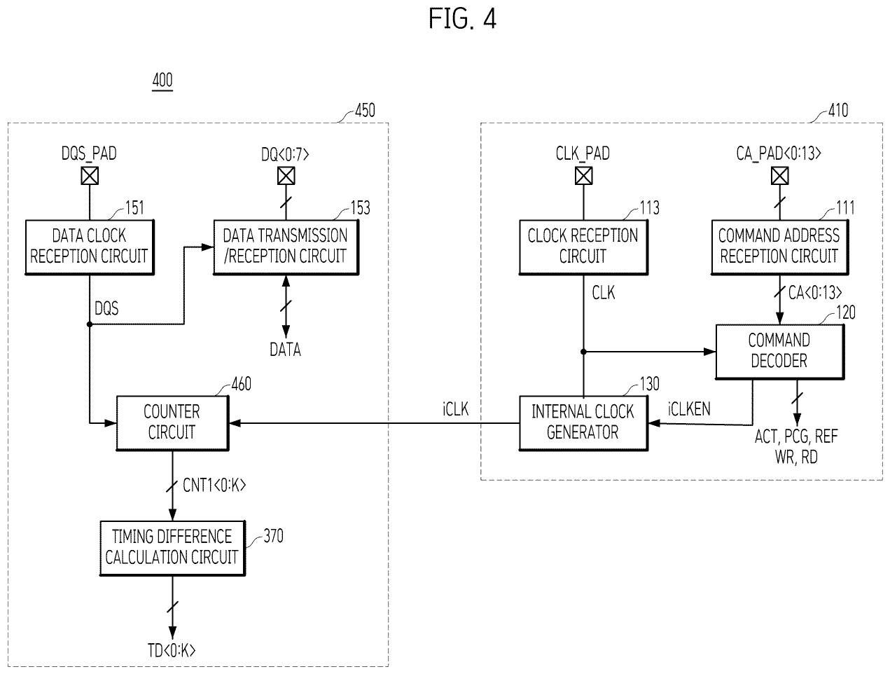

FIG. 4 is a diagram illustrating a configuration of a memory 400 in accordance with a third embodiment of the present disclosure.

Referring to FIG. 4, the memory 400 may include a command block (i.e., a command component) 410 and a data block (i.e., a data component) 450.

In an embodiment, the command block 410 may include the command address reception circuit 111, the clock reception circuit 113, the command decoder 120, and the internal clock generator 130.

The command address reception circuit 111 may receive the command address signals CA<0:13> of the command address terminals CA_PAD<0:13>. The clock reception circuit 113 may receive the clock CLK of the clock terminal CLK_PAD.

The command decoder 120 may decode the command address signals CA<0:13>. In an embodiment, the command decoder 120 may operate in synchronization with the clock CLK. The command decoder 120 may generate the internal command signals ACT, PCG, REF, WR, and RD as a result of decoding. The active signal ACT is an internal command signal instructing an active operation, the precharge signal PCG is an internal command signal instructing a precharge operation, and the refresh signal REF is an internal command signal instructing a refresh operation. The write signal WR is an internal command signal instructing a write operation, and the read signal RD is an internal command signal instructing a read operation.

When the reception of the measurement command is confirmed as a result of decoding the command address signals CA<0:13>, the command decoder 120 may activate the internal clock activation signal iCLKEN after the N clock cycles, where N is an integer equal to or greater than 0, from the reception time point of the measurement command. In an embodiment, the measurement command may be a command for measuring the timing difference between the command block 110 and the data block 150.

The internal clock generator 130 may generate the internal clock iCLK identical to the clock CLK while the internal clock activation signal iCLKEN is activated, and deactivate the internal clock iCLK while the internal clock activation signal iCLKEN is deactivated. In an embodiment, deactivating the internal clock iCLK means fixing the logic level of the internal clock iCLK so that the internal clock iCLK does not toggle.

In an embodiment, the data block 450 may include the data clock reception circuit 151, the data transmission/reception circuit 153, a counter circuit 460, and a timing difference calculation circuit 370.

The data clock reception circuit 151 may receive the data clock DQS of the data clock terminal DQS_PAD. The data clock DQS may be a data clock used for transmitting/receiving the data DATA. In an embodiment, the data clock DQS toggles when the data DATA is transmitted/received and is deactivated in a section where the data DATA is not transmitted/received. During a measurement operation in which a measurement command is applied, the data clock DQS starts toggling after the M clock cycles, where M is an integer greater than N, from the application of the measurement command.

The data transmission/reception circuit 153 may receive the data DATA of the data terminals DQ<0:7> or transmit the data DATA to the data terminals DQ<0:7>. In an embodiment, the data transmission/reception circuit 153 may perform transmission/reception operations in synchronization with the data clock DQS.

The counter circuit 460 may be activated after the power-up of the memory 400 and generate a counting code CNT<0:k> by counting the number of activations of the internal clock iCLK up to the toggling time point of the data clock DQS. The internal clock iCLK may be a clock that is activated after the N clock cycles from the reception time point of the measurement command and is transmitted from the command block 410 to the data block 450, and the data clock DQS may be a clock that is activated after the M clock cycles from the reception time point of the measurement command and is input to the data block 450. The code value of the counting code CNT<0:k> may correspond to the time from the toggling time point of the internal clock iCLK transmitted to the data block 450 to the time point at which the data clock DQS starts toggling. That is, the code value of the counting code CNT<0:k> in FIG. 4 corresponds to the difference between the code value of the first counting code CNT1<0:k> and the code value of the second counting code CNT2<0:k> in FIG. 1.

The timing difference calculation circuit 370 may generate the difference between the value of (M-N) and the value of the counting code CNT<0:k> as the command-data timing difference TD<0:k>. For example, when M=10, N=5, and the value of the counting code CNT<0:k is 3, the command-data timing difference TD<0:k> is generated as 2. The command-data timing difference TD<0:k> calculated by the timing difference calculation circuit 370 is used for controlling the data block 450 of the command block 410.

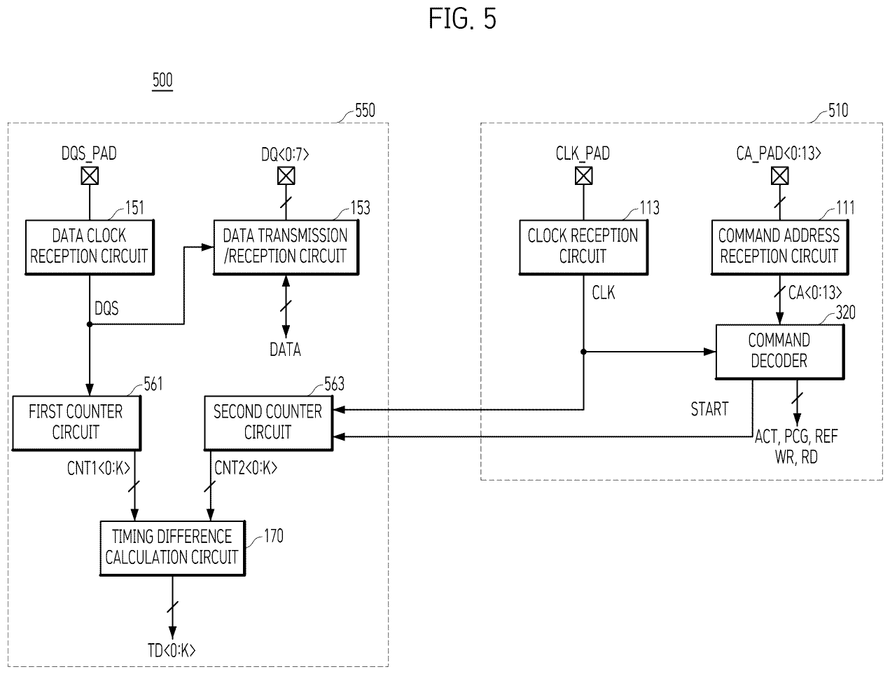

FIG. 5 is a diagram illustrating a configuration of a memory 500 in accordance with a fourth embodiment of the present disclosure.

Referring to FIG. 5, the memory 500 may include a command block (i.e., a command component) 510 and a data block (i.e., a data component) 550.

In an embodiment, the command block 510 may include the command address reception circuit 111, the clock reception circuit 113, and the command decoder 320.

The command address reception circuit 111 may receive the command address signals CA<0:13> of the command address terminals CA_PAD<0:13>. The clock reception circuit 113 may receive the clock CLK of the clock terminal CLK_PAD.

The command decoder 320 may decode the command address signals CA<0:13>. In an embodiment, the command decoder 320 may operate in synchronization with the clock CLK. The command decoder 320 may generate the internal command signals ACT, PCG, REF, WR, and RD as a result of decoding. The active signal ACT is an internal command signal instructing an active operation, the precharge signal PCG is an internal command signal instructing a precharge operation, and the refresh signal REF is an internal command signal instructing a refresh operation. The write signal WR is an internal command signal instructing a write operation, and the read signal RD is an internal command signal instructing a read operation.

When the reception of the measurement command is confirmed as a result of decoding the command address signals CA<0:13>, the command decoder 320 may activate the start signal START after the N clock cycles from the reception time point of the measurement command. In an embodiment, the measurement command may be a command for measuring the timing difference between the command block 510 and the data block 550.

The clock CLK received by the clock reception circuit 113 of the command block 510 and the start signal START generated by the command decoder are transmitted to the data block 550.

The data block 550 may include the data clock reception circuit 151, the data transmission/reception circuit 153, a first counter circuit 561, a second counter circuit 563, and the timing difference calculation circuit 170.

The data clock reception circuit 151 may receive the data clock DQS of the data clock terminal DQS_PAD. The data clock DQS may be a data clock used for transmitting/receiving the data DATA. In an embodiment, the data clock DQS toggles when the data DATA is transmitted/received and is deactivated in a section where the data DATA is not transmitted/received. In an embodiment, during a measurement operation in which a measurement command is applied, the data clock DQS starts toggling after the M clock cycles, where M is an integer greater than N, from the application of the measurement command.

The data transmission/reception circuit 153 may receive the data DATA of the data terminals DQ<0:7> or transmit the data DATA to the data terminals DQ<0:7>. In an embodiment, the data transmission/reception circuit 153 may perform transmission/reception operations in synchronization with the data clock DQS.

In an embodiment, the first counter circuit 161 may generate the first counting code CNT1<0:k> by counting the number of activations of the data clock DQS received by the data clock reception circuit 151. The second counter circuit 163 may generate a second counting code CNT2<0:k> by counting the number of activations of the clock CLK transmitted from the command block 510 from the activation time point of the start signal START transmitted from the command block 510.

The timing difference calculation circuit 170 may calculate a command-data timing difference TD<0:k> by using the first counting code CNT1<0:k> and the second counting code CNT2<0:k>. In an embodiment, the timing difference calculation circuit 170 may calculate the command-data timing difference TD<0:k> by using a difference between the code values of the first counting code CNT1<0:k> and the second counting code CNT2<0:k>.

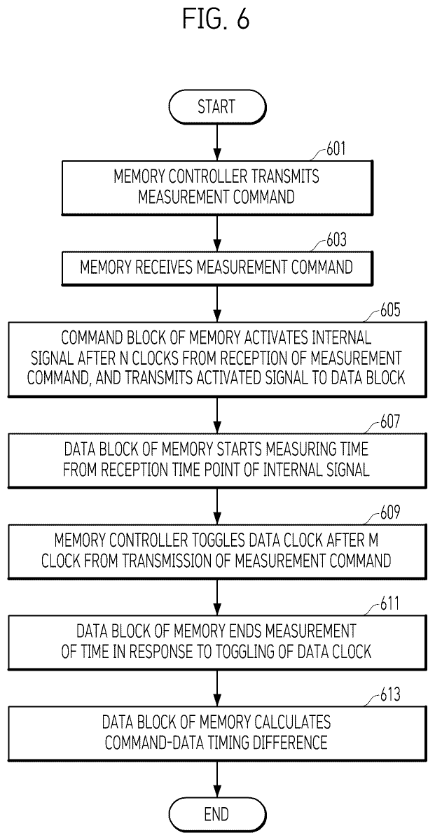

FIG. 6 is a flowchart illustrating an operation of a memory system for measuring the timing difference between the command block and the data block of the memory according to an embodiment of the present disclosure.

Referring to FIG. 6, the memory controller may transmit the measurement command to the memories 100, 300, 400, and 500 (at operation 601). Subsequently, the command blocks 110, 310, 410, and 510 of the memories 100, 300, 400, and 500 receive the measurement command (at operation 603).

The command blocks 110, 310, 410, and 510 of the memories 100, 300, 400, and 500 may activate an internal signal after the N clock cycles from the reception of the measurement command, and transmit the activated signal to the data blocks 150, 350, 450, and 550 (at operation 605). The command blocks 110 and 410 may activate the internal clock iCLK after the N clock cycles from the reception of the measurement command and transmit the activated clock to the data blocks 150 and 450. The command blocks 310 and 510 may activate the start signal START after the N clock cycles from the reception of the measurement command and transmit the activated signal to the data blocks 350 and 550.

The data blocks 150, 350, 450, and 550 of the memories 100, 300, 400, and 500 may start measuring the time from the reception time point of the internal signal (at operation 607). The data blocks 150 and 550 may start counting the second counting code CNT2<0:k>, and the data blocks 350 and 450 may start counting the counting code CNT<0:k>.

The memory controller may toggle the data clock DQS transmitted to the data blocks 150, 350, 450, and 550 of the memories 100, 300, 400, and 500 from the time point after the M clock from the transmission of the measurement command (at operation 609). Subsequently, in response to the toggling of the data clock DQS, the data blocks 150, 350, 450, and 550 of the memories 100, 300, 400, and 500 end the measurement of the time started in operation 607 (at operation 611). The memories 100, 300, 400, and 500 may measure the time from the time point when the data blocks 150, 350, 450, and 550 receive the internal signal to the toggling time point of the data clock DQS.

Subsequently, the timing difference calculation circuit 170 of the data blocks 150 and 550 of the memories 100 and 500 and the timing difference calculation circuit 370 of the data blocks 350 and 450 of the memories 300 and 400 may calculate the command-data timing difference TD<0:k> based on the measured time (at operation 613).

Although the technical spirit of the present invention has been specifically described according to the above embodiments, it should be noted that the above embodiments are for description, not for its limitation. Furthermore, those skilled in the art will understand that various embodiments can be made within the scope of the technical spirit of the present disclosure. Furthermore, the embodiments may be combined to form additional embodiments.

What is claimed is:

1. A memory comprising:
a command component configured to activate an internal clock after N clock cycles from a reception time point of a measurement command, where N is an integer equal to or greater than 0; and
a data component configured to generate a first counting code by counting a data clock, generate a second counting code by counting the internal clock transmitted from the command component, and calculate a command-data timing difference based on a difference between code values of the first counting code and the second counting code.

2. The memory of claim 1, wherein the command component comprises:
a command address reception circuit configured to receive a plurality of command address signals;
a clock reception circuit configured to receive a clock;
a command decoder configured to decode the command address signals and generate an internal clock activation signal that is activated after the N clock cycles from the reception time point of the measurement command; and
an internal clock generator configured to generate the clock as the internal clock when the internal clock activation signal is activated, and fix a level of the internal clock when the internal clock activation signal is deactivated.

3. The memory of claim 1, wherein the data component comprises:
a data clock reception circuit configured to receive the data clock;
a data transmission and reception circuit configured to transmit and receive the data;
a first counter circuit configured to generate the first counting code by counting the data clock;
a second counter circuit configured to generate the second counting code by counting the internal clock; and
a timing difference calculation circuit configured to calculate the command-data timing difference based on the difference between the code values of the first counting code and the second counting code.

4. The memory of claim 3,
wherein a difference corresponding to M clock cycles exists between an application time point of the measurement command to the memory and a time point at which the data clock starts toggling, where M is an integer greater than N, and
wherein the timing difference calculation circuit is configured to calculate, as the command-data timing difference, a difference between a value corresponding to “M-N” and the difference between the code values.

5. The memory of claim 1, wherein the command-data timing difference is used for one or more of write latency control, read latency control, and on-die termination control.

6. A memory comprising:
a command component configured to generate a start signal that is activated after N clock cycles from a reception time point of a measurement command and receives a clock, where N is an integer equal to or greater than 0; and
a data component configured to generate a counting code by counting the clock transmitted from the command component from an activation time point of the start signal transmitted from the command component to a toggling time point of a data clock, and calculate a command-data timing difference based on the counting code.

7. The memory of claim 6, wherein the command component comprises:
a command address reception circuit configured to receive a plurality of command address signals;
a clock reception circuit configured to receive a clock; and
a command decoder configured to decode the plurality of command address signals and generate the start signal that is activated after the N clock cycles from the reception time point of the measurement command.

8. The memory of claim 6, wherein the data component comprises:
a data clock reception circuit configured to receive the data clock;
a data transmission and reception circuit configured to transmit and receive the data;
a counter circuit configured to be activated in response to the start signal, be deactivated in response to toggling of the data clock, and generate the counting code by counting the clock; and
a timing difference calculation circuit configured to calculate the command-data timing difference based on the counting code.

9. The memory of claim 8,
wherein a difference corresponding to M clock cycles exists between an application time point of the measurement command to the memory and a time point at which the data clock starts toggling, where M is an integer greater than N, and
wherein the timing difference calculation circuit is configured to calculate, as the command-data timing difference, a difference between a value corresponding to “M-N” and a value of the counting code.

10. A memory comprising:
a command component configured to activate an internal clock after N clock cycles from a reception time point of a measurement command, where N is an integer equal to or greater than 0; and
a data component configured to generate a counting code by counting the internal clock transmitted from the command component up to a toggling time point of a data clock, and calculate a command-data timing difference based on the counting code.

11. The memory of claim 10, wherein the command component comprises:
a command address reception circuit configured to receive a plurality of command address signals;
a clock reception circuit configured to receive a clock;
a command decoder configured to decode the command address signals and generate an internal clock activation signal that is activated after the N clock cycles from the reception time point of the measurement command; and
an internal clock generator configured to generate the clock as the internal clock when the internal clock activation signal is activated, and fix a level of the internal clock when the internal clock activation signal is deactivated.

12. The memory of claim 10, wherein the data component comprises:
a data clock reception circuit configured to receive the data clock;
a data transmission and reception circuit configured to transmit and receive the data;
a counter circuit configured to generate the counting code by counting the internal clock up to the toggling time point of the data clock; and
a timing difference calculation circuit configured to calculate the command-data timing difference based on the counting code.

13. The memory of claim 12,
wherein a difference corresponding to M clock cycles exists between an application time point of the measurement command to the memory and a time point at which the data clock starts toggling, where M is an integer greater than N, and
wherein the timing difference calculation circuit is configured to calculate, as the command-data timing difference, a difference between a value corresponding to “M-N” and a value of the counting code.

14. A memory comprising:
a command component configured to generate a start signal that is activated after N clock cycles from a reception time point of a measurement command and receive a clock, where N is an integer equal to or greater than 0; and
a data component configured to generate a first counting code by counting a data clock, generate a second counting code by counting the clock transmitted from the command component from an activation time point of the start signal transmitted from the command component, and calculate a command-data timing difference based on a difference between code values of the first counting code and the second counting code.

15. The memory of claim 14, wherein the command component comprises:
a command address reception circuit configured to receive a plurality of command address signals;
a clock reception circuit configured to receive a clock; and
a command decoder configured to decode the plurality of command address signals and generate the start signal that is activated after the N clock cycles from the reception time point of the measurement command.

16. The memory of claim 14, wherein the data component comprises:
a data clock reception circuit configured to receive the data clock;
a data transmission and reception circuit configured to transmit and receive the data;
a first counter circuit configured to generate the first counting code by counting the data clock;
a second counter circuit configured to generate the second counting code by counting the clock from the activation time point of the start signal; and
a timing difference calculation circuit configured to calculate the command-data timing difference based on the difference between the code values of the first counting code and the second counting code.

17. The memory of claim 16,
wherein a difference corresponding to M clock cycles exists between an application time point of the measurement command to the memory and a time point at which the data clock starts toggling, where M is an integer greater than N, and
wherein the timing difference calculation circuit is configured to calculate, as the command-data timing difference, a difference between a value corresponding to “M-N” and the difference between the code values.

18. An operation method of a memory system including a memory controller and a memory, the operation method comprising:
transmitting, by the memory controller, a measurement command to the memory;
receiving, by the memory, the measurement command;
activating, by the memory, an internal signal after N clock cycles from the reception of the measurement command, where N is an integer equal to or greater than 0;
starting, by the memory, measuring a time in response to the activating of the internal signal;
toggling, by the memory controller, a data clock transmitted to the memory from a time point after M clock cycles from the transmission of the measurement command, where M is an integer greater than N;
ending, by the memory, the measuring of the time in response to the toggling of the data clock; and
calculating, by the memory, a command-data timing difference based on the measured time.

19. The operation method of a memory system of claim 18,
wherein the internal signal is an internal clock, and
wherein starting the measuring includes starting measuring the time in response to toggling of the internal clock.

20. The operation method of a memory system of claim 18,
wherein the internal signal is a start signal, and
wherein starting the measuring includes starting measuring the time in response to an activation of the start signal.

21. The operation method of a memory system of claim 18,
wherein the command-data timing difference is used for one or more of write latency control, read latency control, and on-die termination control.
